(19) United States
(12) Patent Application Publication
(10) Pub. No.: US 2011/0036390 A1
(43) Pub. Date: Feb. 17, 2011

(54) COMPOSITE ENCAPSULANTS CONTAINING FILLERS FOR PHOTOVOLTAIC MODULES

(75) Inventors: Donald S. Nelson, San Ramon, CA (US); Todd Krajewski, Mountain View, CA (US)

Correspondence Address: Weaver Austin Villeneuve & Sampson LLP-MSOL;Attn: MIASOLE, P.O. Box 70250, Oakland, CA, 94612-0250, US

(73) Assignee: MIASOLE, Santa Clara, CA (US)

(21) Appl. No.: 12/838,365

(22) Filed: Jul. 16, 2010

Related U.S. Application Data
(63) Continuation-in-part of application No. 12/539,054, filed on Aug. 11, 2009.
Application No. 12/539,054 is a continuation-in-part of application No. 12/639,346, filed on Dec. 16, 2009.

(51) Int. Cl. H01L 31/048; H01L 31/18

(52) U.S. Cl. 136/251; 438/66; 438/80; 257/E31.113

(57) ABSTRACT

Provided are novel photovoltaic module structures and fabrication techniques that include a composite encapsulant disposed and substantially filling voids between at least one sealing sheet and one or more photovoltaic cells. The composite encapsulant contains a bulk encapsulant and filler uniformly distributed throughout the bulk encapsulant. In certain embodiments, at least about 30% by weight of the composite encapsulant is the filler. Adding certain fillers into polymer-based bulk encapsulants in such large amounts reduces encapsulation costs and improves certain performance characteristics of the resulting composite encapsulants. In certain embodiments, the composite encapsulants have better temperature stability, UV stability, mechanical integrity, and/or adhesion than traditional encapsulants. Also, in certain embodiments, the added fillers do not substantially alter the optical properties of initial bulk encapsulants. The composite encapsulants are particularly useful for a front light-incident side of a module.

### CROSS-REFERENCE TO RELATED APPLICATIONS

This application is a continuation-in-part and claims the benefit of U.S. Ser. No. 12/539,054, entitled “CTE MODULATED ENCAPSULANTS FOR SOLAR MODULES,” filed on Aug. 11, 2009, which is incorporated herein by reference in its entirety for all purposes.

This application is also a continuation-in-part and claims the benefit of U.S. Ser. No. 12/639,346, entitled “ORIENTED REINFORCEMENT FOR FRAMELESS SOLAR MODULES,” filed on Dec. 16, 2009, which is incorporated herein by reference in its entirety for all purposes.

### BACKGROUND

Photovoltaic cells are widely used for electricity generation, with multiple photovoltaic cells interconnected in module assemblies. Such modules may in turn be arranged in arrays to convert solar energy into electricity by the photovoltaic effect. Photovoltaic cells are typically protected inside the modules by two sealing sheets and two encapsulant layers. With increasingly complex photovoltaic module designs come demands for enhanced functionalities of encapsulant materials. For example, encapsulant materials covering the light-incident side of the cells need to be highly transmissive to the energy generating solar spectrum. Encapsulant materials in general need to prevent moisture from getting inside the modules and preserve the overall mechanical integrity of the module in conjunction with other module components to reliably function through module manufacturing, testing, and operation.

### SUMMARY

Provided are novel photovoltaic module structures and fabrication techniques that include a composite encapsulant disposed and substantially filling voids between at least one sealing sheet and one or more photovoltaic cells. The composite encapsulant contains a bulk encapsulant and filler uniformly distributed throughout the bulk encapsulant. In certain embodiments, at least about 30% by weight of the composite encapsulant is the filler. Adding certain fillers into polymer-based bulk encapsulants in such large amounts reduces encapsulation costs and improves certain performance characteristics of the resulting composite encapsulants. In certain embodiments, the composite encapsulants have better temperature stability, UV stability, mechanical integrity, and/or adhesion than traditional encapsulants. Also, in certain embodiments, the added fillers do not substantially alter the optical properties of initial bulk encapsulants. The composite encapsulants are particularly useful for a front light-incident side of a module.

In certain embodiments, a photovoltaic module includes a sealing sheet, multiple interconnected photovoltaic cells forming a topographically even or uneven surface facing the sealing sheet, and a composite encapsulant disposed and substantially filling voids between the sealing sheet and cells' uneven surface. The composite encapsulant includes a bulk encapsulant and a filler. The filler is uniformly distributed throughout the composite encapsulant. In certain embodiments, at least about 30% by weight of the composite encapsulant is the filler or, more particularly, at least about 50% by weight. A sealing sheet may be a flexible sheet or a rigid sheet, such as a glass panel.

In certain embodiments, a composite encapsulant forms a layer having an average thickness of between about 2 mils and 60 mils or, more particularly, between about 2 mils and 16 mils (i.e., thin encapsulant layers for low profile topologies) or, in other embodiments, between about 16 mils and 40 mils (i.e., thick encapsulant layers for high profile topologies). In certain embodiments, a composite encapsulant is used for a front light-incident side of a photovoltaic module. A filler may be configured such that it does not substantially alter an optical transmission of the initial bulk encapsulant when the two form a composite encapsulant. In certain embodiments, a filler is made from materials that have similar refractive index to that of the bulk encapsulant. In certain embodiments, a difference between refractive indexes of a filler and a bulk encapsulant is less than about 0.25. A refractive index of a filler is between about 1.5 and 1.7 in certain embodiments.

In the same or other embodiments, surfaces of filler particles may be specifically treated to improve filler's compatibility with a bulk-encapsulant. For example, filler particles may have been surface-treated to improve their wettability by a hulk encapsulant and/or to improve their adhesion to a bulk encapsulant. In the same or other embodiments, a filler includes a UV-resistant filler material, such as one or more inorganic materials. For example, a filler can be made from one or more of the following materials: glass fibers, glass beads, fumed silica, precipitated silica, and sol-gel silica. In a specific embodiment, a filler includes multiple randomly oriented fibers.

In certain embodiments, the photovoltaic cells are copper indium gallium selenide (CIGS) cells. A composite encapsulant can be also used with other types of thin-film cells. A bulk encapsulant may include a thermoplastic olefin (TPO). In the same or other embodiments, a bulk encapsulant includes a silicone-based amorphous thermoplastic material. In general, examples of bulk encapsulants include polyethylene, polypropylenes, polybutylenes, polyethylene terephthalates (PET), polybutylene terephthalates (PBT), polystyrenes, polycarbonates, fluoropolymers, acrylics, ionomers, and silicones.

In certain embodiments, a photovoltaic module also includes a second sealing sheet on another side of the photovoltaic cells and a second composite encapsulant disposed between the second sealing sheet and that other side. The second composite encapsulant may also include a bulk encapsulant and a filler uniformly distributed throughout the hulk encapsulant. A composition of the second composite encapsulant may be the same as that of the first composite encapsulant. In other embodiments, the two composite encapsulants have different compositions, e.g., different bulk encapsulants and/or fillers are used for each. For example, composite encapsulant layers may he light transmissive on the front light incident side and opaque on the back side. Furthermore, one composite encapsulant may be on generally thicker than another encapsulant. For example, a front light-incident side of the photovoltaic cells may be more topographically uneven than the backside, and a thicker composite encapsulant layer is used for that side.

In certain embodiments, a method of fabricating a photovoltaic module involves forming a stack that includes a sealing sheet, one or more photovoltaic cells forming a topographically even or uneven surface facing the sealing sheet, and a composite encapsulant disposed between the sealing sheet and uneven surface. The composite encapsulant includes a bulk encapsulant and a filler distributed substantially uniformly throughout the bulk encapsulant. In certain embodiments, at least about 30% by weight of the composite encapsulant is the filler. The method may also involve laminating the stack to redistribute the composite encapsulant and to substantially fill voids between the sealing sheet and uneven surface. In certain embodiments, a bulk encapsulant and a filler are integrated into one composite encapsulant layer during the lamination. In certain embodiments, forming a stack involves mixing a bulk encapsulant provided in a liquid form with a filler, e.g., filler particles, to form a composite encapsulant and then depositing this composite encapsulant onto a topographically uneven surface of one or more photovoltaic cells. In certain embodiments, substantially uniform distribution of a filler in a bulk encapsulant is achieved during lamination of the photovoltaic module.

These and other aspects of the invention are described further below with reference to the figures.

### BRIEF DESCRIPTION OF THE DRAWINGS

FIG. 1A is a schematic representation of various components of a photovoltaic module prior to lamination of the module in accordance with certain embodiments.

FIG. 1B is a schematic representation of a photovoltaic module after lamination of the module in accordance with certain embodiments.

FIG. 2 is a process flowchart corresponding to a method of fabricating a photovoltaic module containing a composite encapsulant in accordance with certain embodiments.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

### Introduction

Encapsulants are used in photovoltaic modules to encapsulate and protect fragile photovoltaic cells from environmental conditions and mechanical stresses. A typical module has two sealing sheets with one or more photovoltaic cells positioned between the sheets. Encapsulant layers may be provided between one or both sealing sheets and photovoltaic cells. The two encapsulant layers are generally referred to as a front light-incident encapsulant layer and a back encapsulant layer. The front encapsulant layer must be sufficiently transmissive (e.g., having a high optical clarity and low haze) to allow sufficient exposure of the cells to sunlight. In general, encapsulant layers need to have high impact resistance, good shock absorbance, high ultraviolet (UV) light resistance and UV blocking properties, long term thermal stability, good adhesion to sealing sheets (e.g., glass) and other module components, low moisture absorption and high moisture resistance, long term weather-ability, and various other properties.

Encapsulants protect photovoltaic cells by filling voids in between the cells and sealing sheets. Photovoltaic cells often have uneven surfaces caused, for example, by cell interconnects (e.g., current collectors, bypass diodes, and other components). Voids can result from such uneven surfaces, as well as lamination operation defects, and losses in adhesive properties of module components. Voids can lead to moisture permeation, distortion of optical properties, and other undesirable consequences. Encapsulants are configured to fill these voids, for example, during a lamination operation as explained further below. Encapsulants may include thermoplastic polymers that are redistributed during lamination and pushed into void spaces. However, many traditional encapsulant materials are expensive. Encapsulant costs are particularly prohibitive when used as thick layers, e.g., more than 20 mils thick. Furthermore, many traditional encapsulants do not have all of the characteristics listed above. For example, many encapsulants tend to loose their transmissive properties and become yellow after prolonged exposure to sun light. Many encapsulants tend to lose their adhesive strength to sealing sheets and photovoltaic cells after being exposed to wet conditions, which may result in delamination. Because photovoltaic modules are expected to operate for many years under severe environmental conditions, such as direct sunlight, seasonal and daily temperature fluctuations, humidity fluctuations caused by rains and fogs, and mechanical stresses caused by wind, traditional encapsulants can lead to premature module failure or reduced performance.

It has been found that many performance characteristics and the cost of encapsulant materials can be substantially improved by introducing specifically configured filler materials into bulk encapsulants. For example, a relatively inexpensive inorganic filler, such as glass beads, can be added to some thermoplastic polymers at relative large loading to enhance the polymer's mechanical strength (e.g., impact resistance and shock absorbance), UV light resistance and UV blocking, as well as long term adhesive and thermal stability. In embodiments of the composite encapsulants described herein, fillers occupy at least about 30% by weight of the encapsulant. This is in contrast to functional additives that are added at much lower amounts. The high filler loadings of the composite encapsulants provide increased influence on the composite encapsulant properties.

It has also been found that specific processing techniques and material selections described below can yield composite encapsulants with large filler loadings (e.g., at least about 30% and even at least about 70% by weight) that were not previously available for photovoltaic applications. Conventional photovoltaic encapsulants are almost exclusively free of fillers. Integrating fillers into encapsulants in a way that does not compromise performance of photovoltaic modules is a complex task. This task is even more challenging for integrating fillers into encapsulants at the high loadings that are described herein.

### Photovoltaic Module Examples

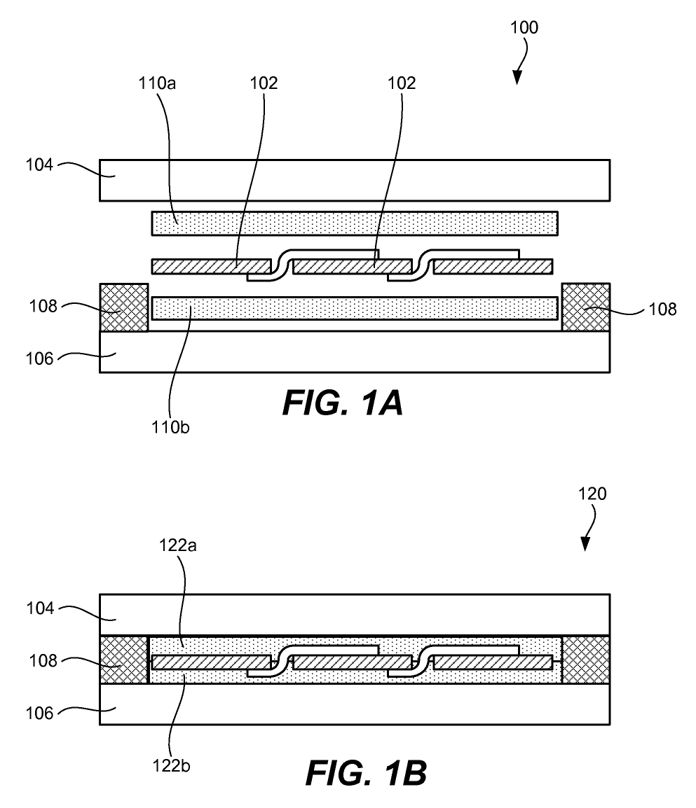

Novel composite encapsulants will now be described in more detail in the context of photovoltaic module structures and fabrication techniques. In general, the composite encapsulants can be used with any photovoltaic module. FIGS. 1A and 1B are schematic representations of one example of a photovoltaic module before and after lamination of the module in accordance with certain embodiments. A module 100 includes one or more interconnected photovoltaic cells 102 positioned between a front light-incident sealing sheet 104 and a back sealing sheet 106. These sheets are used for environmental protection and/or mechanical support of the cells and have generally flat surfaces relative to small topography variations of the cells 102. The topography variations can cause voids if not adequately filled. One or more encapsulant layers 110a and 110b (corresponding to elements 122a and 112b after the lamination operation as shown in FIG. 1B) are provided between the cells 102 and one or both sealing sheets 104 and 106 to substantially fill any voids inside the laminated module 120.

Front sheet 104 and back sheet 106 may be made from various materials that provide the protective and support functions described above. Sealing sheets can be rigid plates and/or flexible sheets. For example, both front and bottom sheets may be made from rigid glass sheets. In another example, a front sheet is made from glass, while a back sheet is made from one or more flexible polymers. In yet another example, both sheets are flexible. Example of materials that can be used for sealing sheets include various glass and polymer materials, such as window glass, plate glass, silicate glass, low iron glass, tempered glass, tempered CeO-free glass, float glass, colored glass, and the like. Examples of polymer materials include polyethylene terephthalate), polycarbonate, polypropylene, polyethylene, polypropylene, cyclic polyolefins, norbornene polymers, polystyrene, syndiotactic polystyrene, styrene-acrylate copolymers, acrylonitrile-styrene copolymers, poly(ethylene naphthalate), polyethersulfone, polysulfone, nylons, poly(urethanes), acrylics, cellulose acetates, cellulose triacetates, cellophane, vinyl chloride polymers, polyvinylidene chloride, vinylidene chloride copolymers, fluoropolymers, polyvinyl fluoride, poly vinylidene fluoride, polytetrafluoroethylene, ethylene-tetrafluoroethylene copolymer, and the like. A thickness of a sealing sheet may be between about 0.05 millimeters and about 15 millimeters or, more particularly, between about 0.05 millimeters and about 10 millimeters, for example, about 3 millimeters or 4 millimeters.

Front light-incident sheet 104 may be configured to transmit visible and near visible wavelengths, e.g., a portion of sunlight that has wavelengths from about 400 nanometers to about 1100 nanometers. Front sheet 104 may not necessarily and very often will not, transmit all sunlight or even all light in the specified wavelength range. For example, a suitable front sheet may have a luminous transmittance of at least about 50%, or even greater than about 80%, or greater than about 90% (e.g., per ASTM D1003). Front sheet 104 may be configured to block some or most of the UV portion of sun light. In some embodiments, front sheet 104 may have surface treatments and features, such as UV filters, anti-reflective layers, surface roughness, protective layers, moisture barriers, or the like. In the same or other embodiments, front sheet 104 and/or back sheet 106 have an encapsulant bonding layer that enhances adhesion of one or both of these sheets to the composite encapsulant.

Photovoltaic cells 102 may include one of the following types of semiconductor junctions: microcrystalline or amorphous silicon, cadmium telluride (CdTe), copper indium gallium selenide (CIGS) or copper indium selenide (CIS), gallium indium phosphide (GaInP), gallium arsenide (GaAs), dye-sensitized solar cells, and organic polymer solar cells. In particular embodiments, cells 102 are CIGS cells. In addition to a semiconductor junction, cells 102 may have a transparent conductive layer formed over the junction. This conductive layer may include various transparent conductive oxides (TCO), such as tin oxide, fluorine-doped tin oxide, indium tin oxide, zinc-oxide such as zinc oxide doped with aluminum, fluorine, gallium, or boron, indium zinc oxide, cadmium sulfide, and cadmium oxide. A current collector may be provided over the transparent conductive oxide for collecting an electrical current generated by the semiconductor junctions. A current collector may include a conductive epoxy, a conductive ink, a metal, (e.g., copper, aluminum, nickel, or silver or alloy thereof; a wire network, or metallic tabs), a conductive glue, or a conductive plastic. A semiconductor junction may be formed on a metal containing substrate, which provides mechanical support and electrical conductivity. This metal containing substrate may made from stainless steel, aluminum, copper, iron, nickel, silver, zinc, molybdenum, titanium, tungsten, vanadium, rhodium, niobium, chromium, tantalum, platinum, gold, or any alloys. The substrate may include multiple layers, such as a polymer layer coated with a conductive metal. In certain embodiments, photovoltaic cells 102 are coated with one or more functional layers, for example, to improve adhesion to the encapsulant layers. A functional layer may be provided on one side (e.g., over a transparent conductive oxide layer or over a metal containing substrate) or both sides.

In certain embodiments, surfaces of front sheet 104 and/or back sheet 106 may be treated to enhance their adhesion to composite encapsulants and/or a perimeter seal such as described further below. A treatment may involve application of adhesives, primers (e.g., silanes, polyallylamine-based materials), flame treatments, plasma treatments, electron beam treatments, oxidation treatments, corona discharge treatments, chemical treatments, chromic acid treatments, hot air treatments, ozone treatments, ultraviolet light treatments, sand blast treatments, solvent treatments, and the like and combinations thereof.

In certain embodiments, a module includes an edge seal 108 that surrounds the solar cells 102. Edge seal 108 may be used to secure front sheet 104 to back sheet 106 and/or to prevent moisture from penetrating in between these two sheets. Edge seal 108 may be initially (i.e., prior to lamination) positioned on back sheet 106 (as shown in FIG. 1A) or on front sheet 104. Edge seal 108 may be made from certain organic or inorganic materials that have low inherent water vapor transmission rates (WVTR), e.g., typically less than 1-2 g/m²/day. In certain embodiments, edge seal 108 is configured to absorb moisture from inside the module in addition to preventing moisture ingression into the module. For example, a butyl-rubber containing moisture getter or desiccant may be added to edge seal 108. In certain modules, a frame (not shown) engages the module edges and surrounds the module for additional mechanical support.

### Composite Encapsulant Examples

As indicated above, a module includes one or more encapsulant layers 110a and 110b interposed between photovoltaic cells 102 and at least one of both sealing sheets. In certain embodiments illustrated in FIGS. 1A and 1B, a module includes two encapsulant layers, e.g., front encapsulant layer 110a and back encapsulant layer 110b. In certain embodiments, both encapsulant layers are made from the same materials. However, since back encapsulant 110b does not need to transmit light, it may be made from a different material, e.g., an opaque material. The two encapsulant layers may have the same or different thicknesses, e.g., thicknesses may depend on respective topologies of the two surfaces of cells 102. In specific embodiments, the two encapsulant layers have different thicknesses. In certain embodiments, an encapsulant layer may be a single-layer or a multi-layer sheet.

A composite encapsulant containing a bulk encapsulant and filler is used for at least one of encapsulant layers. In certain embodiments, a bulk encapsulant is made of one or more of the following materials: polyolefins (e.g., polyethylene, polypropylene, ethylene and propylene copolymer, polyethylene ionomer, ethylene and ethylene vinyl acetate (EVA) copolymer, crosslinked polyethylene), polyesters (e.g., polyethylene terephthalate, polyethylene naphthalate, polytrimethylene terephthalate, polybutylene terephthalate, polycarbonate), polyamides (e.g., nylon), acrylates (e.g., polymethyl methacrylate, polymethyl acrylate, poly(ethylene-co-butyl acrylate) ionomers), elastomers (e.g. thermoplastic polyurethane, polybutadiene, silicone, polyisoprene, natural rubber), fluoropolymers polyvinylidene fluoride, polyvinyl fluoride, polytetrafluoroethylene), biodegradable polymers (e.g., polylactic acid, polyhydroxybutyrate, polyhydroxyalkanoate), and vinyl polymers (e.g., polyvinyl chloride, polyvinyl acetate, polystyrene). Other examples include various thermoplastic resins, thermoset resins, epoxy resins, plastomers and/or any other suitable chain-like molecules. In specific embodiments, a bulk encapsulant is polyethylene, in particular, linear low density polyethylene. Examples also include SURLYN® thermoplastic ionomeric resins (e.g., PV4000, PV5200, PV5300, or equivalent) and SENTRY GLASS® laminate inter-layers available from DuPont in Wilmington, Del. Additional examples include GENIOMER® 145 thermoplastic silicone elastomers available from Wacker Chemie in Munich, Germany. In specific embodiments, a bulk encapsulant includes a silicone-based amorphous thermoplastic material. Furthermore, a bulk encapsulant may include a thermoplastic olefin (TPO).

As noted above, a filler occupies a substantial portion of a composite encapsulant. In certain embodiments, a composite encapsulant includes at least about 30% by weight of a filler or, more particularly, at least about 40%, at least about 60%, or even at least about 70%. Large amounts of fillers in composite encapsulants are preferable for reasons explained above. Still, sufficient amounts of a bulk encapsulant may be needed to maintain adhesion between the two components of the composite encapsulant and adhesion between the composite encapsulant and other module elements, e.g., photovoltaic cells, front sealing sheets, back sealing sheets. Furthermore, a composite encapsulant should have adequate flowable characteristics during, e.g., lamination to substantially fill voids.

Examples of filler materials include glass (e.g., glass fibers, glass spheres, glass beads, fumed silica, precipitated silica, and sol-gel silica, E-type glass fibers/alumino-borosilicate glass with less than 1 wt % alkali oxides, S-type glass fibers/alumino silicate glass without CaO but with high MgO content), calcium carbonate, calcium silicate, magnesium oxide, aluminum oxide, zinc oxide, titanium oxide, silicon carbide, boron nitride, aluminum nitride, talc, mica, clay, carbon black, zeolites, barite, barium sulfate, high modulus polyimide, linear high molecular weight polyethylene, light transmissive minerals, liquid crystal polymers, and combinations thereof. Filler materials can be in a form of small particles, fibers, flakes, and/or tubes. Filler materials used for a front encapsulant are generally solid structures, which typically provide better light transmission than hollow structures. Filler particles may be between about 0.001 micrometers and 1000 micrometers in size or, more particularly, between about 0.1 micrometers and about 250 micrometers in size, or more particularly, between about 0.2 micrometers to about 50 micrometers. In specific embodiments, a filler includes fibers that have an aspect ratio at least about 10 or, more particularly, at least about 50 or, even more particularly, at least about 100. Such fibers can be randomly oriented in a composite encapsulant.

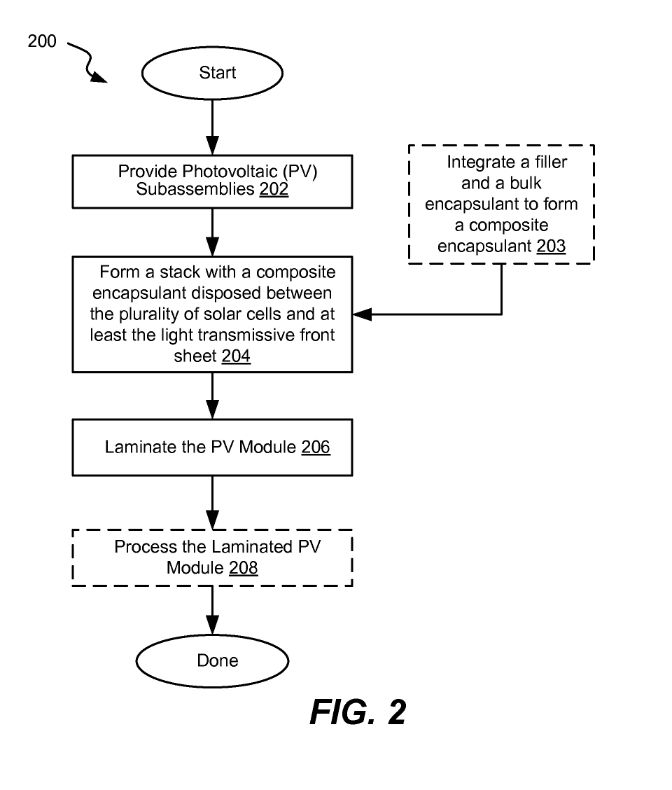

In certain embodiments, a filler is uniformly distributed throughout a bulk encapsulant. For example, filler particles may be combined with a bulk encapsulant prior or during extrusion of a composite encapsulant. Some other embodiments of forming a composite encapsulant from a filler and a bulk encapsulant are described below in the context of FIG. 2. In certain embodiments, a front and/or back encapsulant is a multi-layer structure that includes layers of different composition. A composite encapsulant used for a front light-incident side need to be sufficiently transparent. For example, a luminous transmittance of such sheets may be at least about 75%, or at least about 85% or at least about 90% (e.g., according to ASTM D1003). In certain embodiments, addition of a filler increases a luminous transmittance and/or reduces a yellowness index (e.g., according to ASTM D313) of a composite encapsulant relative to an initial bulk encapsulant. Furthermore, a filler may help retaining these optical properties over a longer period of time.

In general, a filler in a composite encapsulant used for a front light-incident side does not substantially alter the optical properties of an initial bulk encapsulant. For example, a difference between refractive indexes of a filler and bulk encapsulant may be less than about 0.25. In certain embodiments, a filler has a refractive index of between about 1.3 and 1.8 or, more particularly, between about 1.4 and 1.7 or even between about 1.45 and 1.6. A filler used for a front-incident composite encapsulant is typically made of UV-resistant materials, some examples of which are listed above. A UV-resistant filler retains substantially the same optical properties (e.g., luminous transmittance, color) during an entire operating life-span of the module.

In certain embodiments, adding a filler to a bulk encapsulant substantially improves thermal conductivity of the encapsulant layer. Better heat dissipation from photovoltaic panels helps to lower their operating temperatures, which in turn can substantially improve their power output and/or efficiency. Furthermore, a filler may be used to adjust a coefficient of thermal expansion (CTE) of a composite encapsulant to be more in line with that of other module components. In certain embodiments, adding a filler can reduce shrinkage of a composite encapsulant during lamination. This can allow a more aggressive temperature ramping during lamination (e.g., permitting higher process throughputs) and possibly result in fewer remaining voids (e.g., leading to higher production yields).

In certain embodiments, adding a filler improves water vapor transmission (WVTR) characteristics of a resulting composite encapsulant. In certain embodiments, a WVTR of a composite is less than about 1 g/m²-day (according to ASTM F1249). Furthermore, a filler may be used to substantially alter electrical properties of a resulting composite encapsulant, e.g., a surface resistivity, a volume resistivity, and a dielectric constant. Yet another parameter that can be improved by adding a filler is mechanical strength. In certain embodiments, a composite encapsulant has a tensile strength of at least about 2000 psi or, more particularly, at least about 3000 psi, or more particularly at least about 4000 psi, or even at least about 5000 psi. In the same or other embodiments, a tensile strength of a bulk encapsulant is improved by at least about 25% or, more particularly, by at least about 50% or even by at least about 100% by adding a filler. In certain embodiments, a filler helps to retain initial adhesion characteristics of a composite encapsulant. For example, a typical EVA encapsulant looses 50-80% of its initial adhesion strength after being exposed to a 1000-hour damp heat test.

A filler may also be used to modify UV cut-off values of a bulk encapsulant, for example to protect UV sensitive materials positioned under the encapsulant layer. For example, a typical EVA encapsulant has a UV cut-off of about 360 nanometers. A tiller may be used to increase this value in a composite encapsulant to at least about 400 nanometers or, more particularly, to at least about 450 nanometers. A UV cut-off is defined as a wavelength spectrum where an encapsulant or any other material used for a front light-incident side of the module is fully transmissive, i.e., it transmits light in the defined spectrum near or at the maximum of its light transmission capabilities. For example, a typical glass sheet blocks most UV light having a wavelength of less than about 300 nanometers, i.e., glass has a UV cut-off of about 300 nanometers. UV transmission cut-off at the proper wavelength can be used to protect various module components from damaging short wavelengths, still allowing photovoltaic cells to operate near or at their maximum potential.

A composite encapsulant may include various additives besides the bulk encapsulant and filler. Examples of additives include plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, wettability promoters (e.g., surfactants), and the like. In certain embodiments, a composite encapsulant includes one or more adhesion promoters to enhance bonding between the bulk encapsulant and the filler. A number of materials are known to promote bonding between materials identified herein as suitable for bulk encapsulants and fillers. For example, siloxane may be incorporated into a bulk thermoplastic polymer encapsulant to promote adhesion to a glass filler. Additionally, or alternatively, a filler may be treated to enhance bonding to a bulk encapsulant. For example, a glass filler may be silynized.

In the same or other embodiment, a composite encapsulant includes a thermal stabilizer. Examples include phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid, compounds which destroy peroxide, hydroxylamines, nitrones, thiosynergists, benzofuranones, indolinones, and the like and mixtures thereof. In the same or other embodiments, a composite encapsulant includes one or more ITV absorbers. Examples include benzotriazoles, hydroxybenzophenones, hydroxyphenyl triazines, esters of substituted and unsubstituted benzoic acids, and the like and mixtures thereof. In the same or other embodiments, a composite encapsulant includes one or more hindered amine light stabilizers (HALS), such as secondary, tertiary, acetylated, N-hydrocarbyloxy substituted, hydroxy substituted N-hydrocarbyloxy substituted, or other substituted cyclic amines which further incorporate steric hindrance, generally derived from aliphatic substitution on the carbon atoms adjacent to the amine function. A thermal stabilizer, UV absorber, and/or hindered amine light stabilizer could be present in a composite encapsulant in amounts of between about 0 to about 10.0% by weight or more specifically between about 0.1% and 1% by weight.

Returning to FIGS. 1A and 1B, a composite encapsulant may be supplied as a thin sheet (elements 110a and 110b in FIG. 1A), e.g., between about 2 mils and 60 mils, or between about 2 mils and 16 mils (thin encapsulant layers) or between about 16 mils and 60 mils (thick encapsulant layers). During subsequent lamination, encapsulant sheets change their shapes (as shown with elements 122a and 122b FIG. 1B) to fill voids between photovoltaic cells 102. In other embodiments, a composite encapsulant can be provided in a liquid form and coated on a sealing sheet or photovoltaic cells prior to assembling the module. Some of these embodiments are further described below in the context of FIG. 2.

### Process Examples

Provided also are methods of fabricating photovoltaic modules with composite encapsulants. FIG. 2 depicts a process flowchart 200 illustrating certain operations in a process of fabricating photovoltaic modules in accordance with certain embodiments. At 202, various module components and subassemblies are provided. Subassemblies may include a light transmissive front sealing sheet, a back sealing sheet, and one or more photovoltaic cells. In certain embodiments, a front sheet or a back sheet may have an edge seal disposed along the edge of the seal-carrying sheet. If multiple photovoltaic cells are used, the cells may be spatially arranged on one of the sealing sheets and/or interconnected during this operation or other operations. In other embodiments, a set of interconnected and mechanically integrated cells are provided as inlays into this operation. Some examples of module components and subassemblies are provided above.

At 204, a composite encapsulant is disposed between the photovoltaic cells and at least one of the sealing sheets. For example, a composite encapsulant that is pre-formed into a sheet may be provided in a roll. Such a composite encapsulant may be fabricated using blown-film extrusion, calendaring, daring, casting, or other techniques. An encapsulant roll can be unwound to provide an encapsulant sheet of a predetermined size, e.g., determined by a width and/or length of the photovoltaic module. This sheet is then positioned in between the photovoltaic cells and the sealing sheet. In certain embodiments, multiple sheets of the same or different materials (e.g., different compositions) are provided to form a single encapsulant layer.

In other embodiments, a composite encapsulant is formed during the module fabrication process 200. For example, a filler may be combined with a bulk encapsulant in upstream operation 203. A bulk encapsulant may be provided in a liquid form and mixed with filler particles to form a liquid composite encapsulant. This composite encapsulant is then coated onto photovoltaic cells and/or one or both sealing sheets. In certain embodiments, various coupling agents (e.g., glycidoxypropyl trimethoxysilane, amino-propyl triethoxysilane, aluminium, titanate, and titanium composite coupling agents) are used for dispersion of a filler in a bulk encapsulant.

In other embodiments, a filler is combined with a bulk encapsulant during a stack forming operation 204 and/or during lamination operation 206. For example, filler particles may be dispersed over a bulk encapsulant sheet during stacking operation 204 and then integrated into a composite encapsulant layer during lamination operation 206. Specifically, lamination may cause substantially uniform distribution of the bulk encapsulant and the filler is achieved during lamination of the photovoltaic module.

The stack is then laminated (block 206). Laminating redistributes the composite encapsulant such that most voids are filled. Examples of lamination techniques involve autoclave, nip roll, and vacuum lamination. Air is substantially removed from inside the sealed area. Certain filler materials (e.g., glass scrim) may improve air removing properties of a composite encapsulant. Encapsulants are typically heated during the lamination process to soften the encapsulant layer and facilitate adhesion to the photovoltaic cells and sealing sheets. In certain embodiments, a composite encapsulant is heated to at least about 100° C. (e.g.; for silicone based encapsulant) or, more particularly, to at least about 150° C. (e.g., for ethylene-vinyl acetate based encapsulant).

The module fabrication process may continue with various post-lamination operations, such as attaching module connectors and testing modules (block 208).

### CONCLUSION

Although the foregoing invention has been described in some detail for purposes of clarity of understanding, it will be apparent that certain changes and modifications may be practiced within the scope of the appended claims. It should be noted that there are many alternative ways of implementing the processes, systems, and apparatus of the present invention. Accordingly, the present embodiments are to be considered as illustrative and not restrictive, and the invention is not to be limited to the details given herein.

What is claimed is:

1. A photovoltaic module comprising:
a sealing sheet;
a plurality of interconnected photovoltaic cells forming a topographically uneven or even surface facing the sealing sheet; and
a composite encapsulant disposed and substantially filling voids between the sealing sheet and the surface, said composite encapsulant comprising a bulk encapsulant and a filler distributed substantially uniformly throughout the composite encapsulant,
wherein the filler is at least about 30% by weight of the composite encapsulant.

2. The photovoltaic module of claim 1, the filler is at least about 50% by weight of the composite encapsulant.

3. The photovoltaic module of claim 1, wherein the composite encapsulant forms a layer having an average thickness of between about 2 mils and 40 mils.

4. The photovoltaic module of claim 1, wherein the composite encapsulant forms a layer having an average thickness of between about 4 mils and 16 mils.

5. The photovoltaic module of claim 1, wherein the composite encapsulant forms a layer having an average thickness of between about 16 mils and 40 mils.

6. The photovoltaic module of claim 1, wherein the filler does not substantially alter the optical transmission of the bulk encapsulant.

7. The photovoltaic module of claim 1, wherein a difference between the refractive index of the filler and the refractive index of the bulk encapsulant is less than about 0.25.

8. The photovoltaic module of claim 1, wherein the refractive index of the filler is between about 1.5 and 1.7.

9. The photovoltaic module of claim 1, wherein the filler comprises particles that are surface-treated to improve their wettability by the bulk encapsulant.

10. The photovoltaic module of claim 1, wherein the filler comprises particles that are surface-treated to improve their adhesion to the bulk encapsulant.

11. The photovoltaic module of claim 1, wherein the filler comprises a UV-resistant filler material.

12. The photovoltaic module of claim 1, wherein the filler comprises an inorganic material.

13. The photovoltaic module of claim 1, wherein the filler comprises one or more materials selected from the group consisting of glass fibers, glass beads, fumed silica, precipitated silica, and sol-gel silica.

14. The photovoltaic module of claim 1, wherein the filler comprises a plurality of randomly oriented fibers.

15. The photovoltaic module of claim 1, wherein photovoltaic cells in the plurality of interconnected photovoltaic cells are copper indium gallium selenide (CIGS) cells.

16. The photovoltaic module of claim 1, wherein the bulk encapsulant comprises a thermal polymer olefin (TPO).

17. The photovoltaic module of claim 1, wherein the bulk encapsulant comprises a silicone-based amorphous thermoplastic material.

18. The photovoltaic module of claim 1, wherein the bulk encapsulant comprises one or more materials selected from the group consisting of polyethylene, polypropylenes, polybutylenes, polyethylene terephthalates (PET), polybutylene terephthalates (PBT), polystyrenes, polycarbonates, fluoropolymers, acrylics, ionomers, and silicones.

19. The photovoltaic module of claim 1, wherein the sealing sheet comprises a glass panel.

20. The photovoltaic module of claim 1, further comprising
a second sealing sheet facing an opposite side of the plurality of interconnected photovoltaic cells; and
a second composite encapsulant disposed between the second sealing sheet and the opposite side, said second composite encapsulant comprising a bulk encapsulant and a filler distributed substantially uniformly throughout the second composite encapsulant.

21. The photovoltaic module of claim 20, wherein an average thickness of a layer formed by the composite encapsulant is greater than an average thickness of a layer formed by the second composite encapsulant.

22. The photovoltaic module of claim 1, wherein the sealing sheet comprises a flexible sheet.

23. A method of fabricating a photovoltaic module comprising:
(a) forming a stack comprising:
a sealing sheet;
a plurality of interconnected photovoltaic cells forming a topographically uneven or even surface facing the sealing sheet; and
a composite encapsulant disposed between the sealing sheet and the surface, said composite encapsulant comprising a bulk encapsulant and a filler distributed substantially uniformly throughout the composite encapsulant, wherein the filler is at least about 30% by weight of the composite encapsulant; and
(b) laminating the stack to redistribute the composite encapsulant and to substantially fill voids between the sealing sheet and the surface.

24. The method of claim 23, wherein the bulk encapsulant and the filler are integrated into one layer during the lamination.

24. The method of claim 23, wherein forming the stack comprises mixing the bulk encapsulant provided in a liquid form with the filler to form the composite encapsulant and depositing the composite encapsulant onto the topographically uneven or even surface of the plurality of interconnected photovoltaic cells.

25. The method of claim 23, wherein the substantially uniform distribution of the bulk encapsulant and the filler is achieved during lamination of the photovoltaic module.
